(19) United States
(12) Patent Application Publication
(10) Pub. No.: US 2013/0256883 A1
(43) Pub. Date: Oct. 3, 2013

(54) ROTATED SEMICONDUCTOR DEVICE FAN-OUT WAFER LEVEL PACKAGES AND METHODS OF MANUFACTURING ROTATED SEMICONDUCTOR DEVICE FAN-OUT WAFER LEVEL PACKAGES

(71) Applicants: Thorsten Meyer, Regensburg (DE); Bernd Waidhas, Pettendorf (DE); Thomas Ort, Regensburg (DE)

(72) Inventors: Thorsten Meyer, Regensburg (DE); Bernd Waidhas, Pettendorf (DE); Thomas Ort, Regensburg (DE)

(73) Assignee: INTEL MOBILE COMMUNICATIONS GMBH, Neubiberg (DE)

(21) Appl. No.: 13/430,765

(22) Filed: Mar. 27, 2012

(51) Int. Cl. H01L 23/48; H01L 21/60

(52) U.S. Cl. 257/738; 438/121; 257/773; 257/E21.506; 257/E23.021; 257/E23.01

(57) ABSTRACT

In various aspects of the disclosure, a package may be provided. The package may include at least one semiconductor device rotated about an axis with respect to an edge of the package, at least one bond pad on each semiconductor device, and at least one conductive trace electrically connected to the semiconductor device through the at least one bond pad.

### TECHNICAL FIELD

Various aspects of the disclosure relate generally rotated semiconductor device Fan-Out Wafer Level packages and to methods of manufacturing rotated semiconductor device Fan-Out Wafer Level packages.

### BACKGROUND

Today, fabrication of integrated circuit devices typically includes packaging of the integrated circuits or semiconductor devices. Reliability of the packaged device is always a concern, especially with respect to the integrity of the chip/package interconnects.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various aspects of the disclosure of the invention are described with reference to the following drawings, in which:

FIGS. 1A-1C show a semiconductor device arrangement in accordance with an aspect of the disclosure;

FIGS. 2A-2B show a semiconductor device arrangement in accordance with an aspect of the disclosure;

FIG. 3 shows a semiconductor device arrangement in accordance with another aspect of the disclosure;

FIG. 4 shows a semiconductor device arrangement in accordance with another aspect of the disclosure;

FIG. 5A-5B show a semiconductor device arrangement in accordance with another aspect of the disclosure;

FIGS. 6A-6C shows a semiconductor device arrangement in accordance with another aspect of the disclosure;

FIGS. 7A-7B shows a semiconductor device arrangement in accordance with another aspect of the disclosure.

FIG. 8 shows a semiconductor device arrangement in accordance with another aspect of the disclosure.

### DESCRIPTION

In various aspects of the disclosure, semiconductor device arrangements may be provided that may include at least one semiconductor device within a Fan-Out Wafer Level package, in which the semiconductor device is rotated with respect to the edges of the package. The degree of rotation with respect to the edge of the package may include a number of angles, including 22.5°±5°, 22.5°±10°, 45°±5° or 45°±10°, for instance. The rotation of the semiconductor device may decrease the semiconductor device material included in areas with a high difference in coefficient of thermal expansion (silicon to board) in the region of the distance to neutral point from the center of the semiconductor device to the corner of the package, allowing for better thermal cycling performance. The rotated semiconductor device may also allow for improved interconnect routing between the semiconductor device and the underlying ball grid array. Rotation of the semiconductor device may further allow for reduced distance from bond pads located on the semiconductor device corner to the package edge, allowing for shorter interconnects and better electrical performance. Rotation of the semiconductor device may allow for improved routing in package-on-package structures. Rotation of the semiconductor device may also allow for improved usage of the space available in the chip package, allowing for the incorporation of two or more semiconductor devices into a package that previously only accommodated one semiconductor device.

The following detailed description refers to the accompanying drawings that show, by way of illustration, specific details and aspects of the disclosure in which the invention may be practiced. Other aspects of the disclosure may be utilized and structural, logical, and electrical changes may be made without departing from the scope of the invention. The various aspects of the disclosure are not necessarily mutually exclusive, as some aspects of the disclosure can be combined with one or more other aspects of the disclosure to form new aspects of the disclosure. The following detailed description therefore is not to be taken in a limiting sense, and the scope of the present invention is defined by the appended claims.

Various aspects of the disclosure are provided for devices, and various aspects of the disclosure are provided for methods. It will be understood that basic properties of the devices also hold for the methods and vice versa. Therefore, for sake of brevity, duplicate description of such properties may be omitted.

The terms “coupling” or “connection” as used herein may be understood to include a direct “coupling” or direct “connection” as well as an indirect “coupling” or indirect “connection”, respectively.

The terms “disposed over”, “located over” or “arranged over” as used herein are intended to include arrangements where a first element or layer may be disposed, located or arranged directly on a second element or layer with no further elements or layers in-between, as well as arrangements where a first element or layer may be disposed, located or arranged above a second element or layer with one or more additional elements or layers between the first element or layer and the second element or layer.

The term “rotated semiconductor device” as used herein may be understood to indicate that one or more semiconductor devices are rotated about an axis with respect to an enclosing package. For example, in accordance with some aspects of the disclosure, an edge of a semiconductor device may be rotated 45 degrees, ±5 degrees with respect to the edges of the underlying package, resulting in a flat edge of the semiconductor device being directly opposite a corner of the package. However, the term “rotated semiconductor device,” as used herein, includes rotation about any axis or corner of the semiconductor device, and is not intended to imply only rotation about a central axis of the semiconductor device or the package.

The term “bond pad” as used herein may be understood to include, for example, pads that will be contacted in a bonding process (for example, in a wire bonding process, in a flip chip process or in a ball attach process) of a semiconductor device or chip. In case that a ball attach process is applied, the term “ball pad” may also be used.

The term “redistribution trace” as used herein may be understood to include, for example, conductive lines or traces disposed over a semiconductor device's or wafer's active surface and used to relocate a bond pad of the semiconductor device or wafer. In other words, a bond pad's original location over the semiconductor device or wafer may be shifted to a new location by means of a redistribution trace which may serve as an electrical connection between the (relocated) bond pad at the new location and an electrical contact (or pad) at the original location over the semiconductor device or wafer.

The term “redistribution layer (RDL)” as used herein may be understood to refer to a layer including a plurality or set of redistribution traces used to relocate (“redistribute”) a plurality of bond pads of a semiconductor device or wafer.

The term “reconstitution structure” as used herein may be understood to include, for example, a structure that may be formed (e.g. cast) around a semiconductor device to serve as an artificial wafer portion where, for example, additional bond pads may be placed (for example, in addition to bond pads located over the semiconductor device). Bond pads located over the reconstitution structure may be electrically connected to the semiconductor device (e.g. to electrical contacts or pads of the semiconductor device), for example by means of redistribution traces of a redistribution layer. Thus, additional interconnects for a semiconductor device may be realized over the reconstitution structure (so-called “fan-out design”).

The term “embedded wafer level ball grid array (eWLB)” may be understood to refer to a packaging technology for integrated circuits. In an eWLB package, interconnects may be applied on an artificial wafer made of semiconductor device or chips (e.g. silicon semiconductor device or chips) and a casting compound. eWLB may be seen as a further development of the classical wafer level ball grid array technology (WLB or WLP: wafer level package). For example, all process steps for the generation of the package may be performed on the wafer. This may, for example, allow, in comparison to classical packaging technologies (e.g. ball grid array), the generation of very small and flat packages with improved electrical and thermal performance at decreased cost.

The term “thermal cycles to failure” may be understood to refer to a series of tests where a package or device is exposed to repeated heating and cooling cycles (“thermal cycling”) until the device or package experiences electrical or mechanical failure, often through fractures in the packaging or the electrical conductors of the package.

The term “distance to neutral point” (DNP) may be understood to refer to the distance from an input/output location in the package, such as a bond pad or ball pad, to the center of the package. For a symmetricly-oriented package, the neutral point is also the geometric center of the semiconductor device.

In WLB technologies, which are built on a wafer (e.g. silicon wafer), the interconnects (typically solder balls) usually fit on the chip (so-called fan-in design). Therefore, usually only chips with a restricted number of interconnects for a given distance between the interconnects may be packaged.

In contrast thereto, the eWLB technology may allow the realization of semiconductor device or chips with a high number of interconnects. Here, the package may be realized not on a semiconductor wafer (e.g. silicon wafer) as for classical Wafer Level Package, but on an artificial wafer. To this end, a front-end-processed wafer (e.g. silicon wafer) may, for example, be diced and the singulated chips may be placed on a carrier. The distance between the chips may be chosen freely, but may be typically larger than on the (silicon) wafer. The gaps and the edges around the chips may be filled with a casting compound to form a wafer of substrate of other format. After curing, an artificial wafer containing a mold frame around the semiconductor device for carrying additional interconnect elements may be realized. After the build-up of the artificial wafer (the so-called Reconstitution), electrical connections from the chip contacts or pads to the interconnects may, for example, be realized in thin-film technology, like for other classical Wafer Level Package. The electrical connections formed therein are referred to as the “redistribution traces.”

With eWLB technology an arbitrary number of additional interconnects may, in principle, be realized on the package in an arbitrary distance (so-called fan-out design). Therefore the eWLB technology may, for example, also be used for space sensitive applications, where the chip area would not be sufficient to place the needed number of interconnects in a realizable distance. Because there are a finite number of connections which need to be made from a given semiconductor device, this means that there will be a relative depopulation of bond pads from the center of the package area toward the edges of the package.

An eWLB may be seen as one example of a so-called fan-out wafer level package. In addition to eWLB, other types of fan-out wafer level packages are known, for example fan-out wafer level packages that are not cast-based or include so-called embedding technologies.

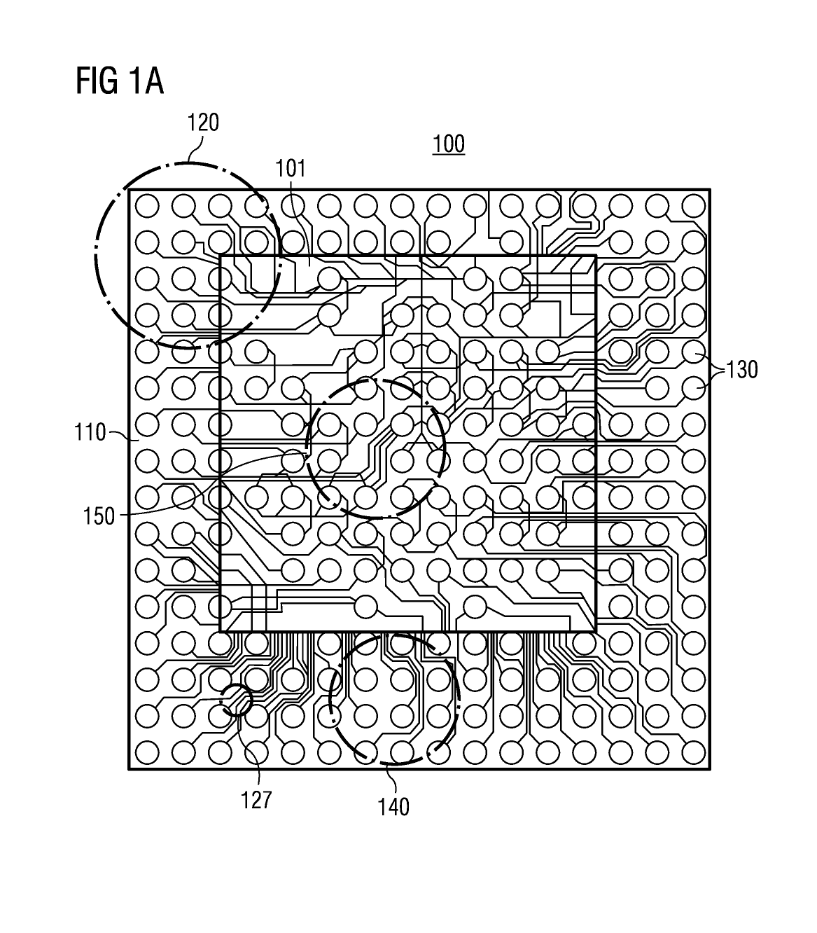

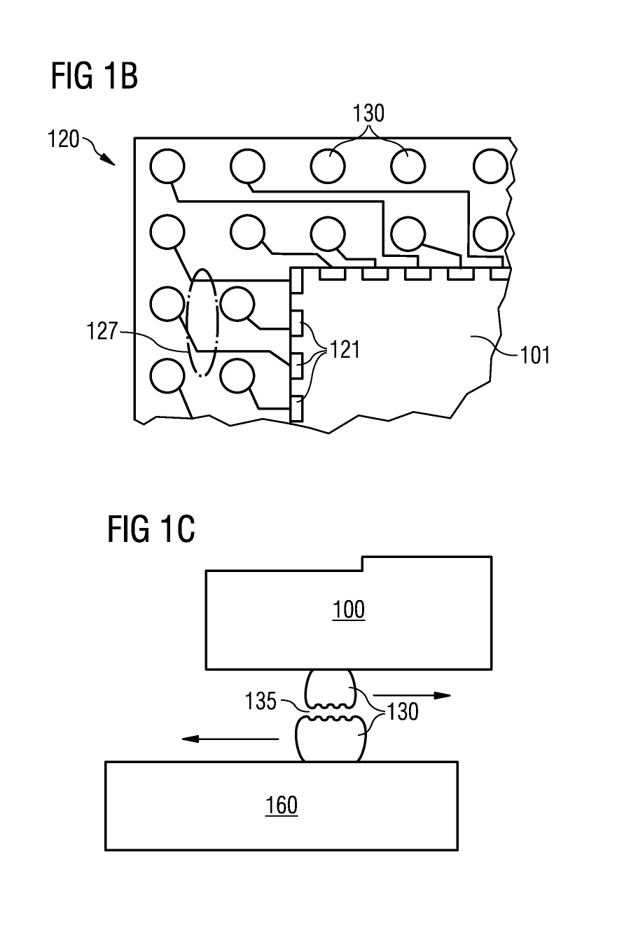

FIG. 1A shows a plan view of an package illustrating an eWLB package manufactured according to current designs.

FIG. 1A illustrates an eWLB package 100 including a semiconductor device 101 and an associated reconstitution structure 110 formed from a polymeric mold compound which forms the rest of the wafer structure within package 100. Reconstitution structure 110 may also be referred to as a mold frame 110. Mold frame 110 may be manufactured out of a mold compound. The mold compound is typically a polymeric material.

There are a plurality of redistribution wiring structures 127 embedded throughout 110, as shown in expanded FIG. 1B. Wiring structures 127 form wiring connects between the chip contacts 121 and the ball grid array, in the form of solder balls 130 at the bottom of the package.

Also shown in FIG. 1A are solder balls 130 attached to the redistribution traces at the bottom of the package. Solder balls 130 are used to electrically connect the package to an underlying printed circuit board (PCB) (not shown). As illustrated in FIG. 1A, the population density of solder balls is typically much higher at the edges 140 of the package than toward the center 150 of the package. In a typical configuration, the majority of the area of semiconductor device 101 is located directly above the depopulated area toward center 150 of the package.

As discussed above, and as illustrated in FIG. 1C, an issue of importance in chip packaging is reliability. A potential factor leading to reduced relibility in packaged chips is failure 135 of the solder bond in a solder ball 130 located between the package 100 and the underlying PCB 160. One cause of these types of failures is fracture due to stress. Exemplary factors that can directly affect the amount of stress on solder ball 130 are the distance to neutral point and the difference between the coefficient of thermal expansion of package 100 and the coefficient of thermal expansion of underlying PCB 160. The greater that distance to neutral point and the greater that difference in thermal expansion, the greater the stress placed on solder ball 130, and the lower the reliability of the bond, where reliability is measured in this instance as the predicted number of thermal cycles to failure.

The arrangement shown in FIG. 1A, with the semiconductor device 101 placed squarely within the package 100, leads to a distance to neutral point (DNP) oriented over a large region of the semiconductor device in the direction of the most extreme bond pads 130 located in the corner of the package, as discussed further below. Therefore, this leads to an increase in stress at bonds in the corners of the package. Similarly, referring again to FIG. 1B, there is a high redistribution line 127 density associated with chip contacts 121 at the corners of semiconductor device 101. The combination of high density of redistribution lines 127 with that of chip contacts 121 at the corner of semiconductor device 101 leads to an area of high stress with respect to the interconnects. This, combined with areas of high DNP and components that have a relative large CTE mismatch can lead to potential reliability problems, especially with respect to thermal cycling, as discussed further below.

In the fabrication of packages, such as for example an embedded wafer level ball grid array (eWLB), a number of different materials must be used. Semiconductor device 101 is typically silicon, reconstitution structure 110 is often predominantly a polymeric mold compound, redistribution layer 127 is a metal or other conductor, and the underlying printed circuit board (PCB) is a metal encased in a laminate polymer. Each of the aforementioned structures has associated with it a unique coefficient of thermal expansion (CTE), which is an inherent property of the material(s) used to form the structure(s). Due to the CTE associated with the various materials, the individual structures will expand or contract in size differently with variations in temperature. Because the CTEs for the various structures are different, the structures will move slightly relative to each other as the temperature of the local environment changes. Expecially with respect to movement between the package and the board, this causes stress in the board elements, especially in the various interconnect elements such as the solder ball connections, leading to solder fatigue in the solder ball. Such movement can then lead to a failure of the packaged device. This is particularly problematic when the packaged device is subjected to thermal cycling.

By way of example, the CTE for a typical silicon-based semiconductor device is in the range of 3 ppm, the CTE for a highly-filled polymeric mold compound is 7 ppm, and the CTE for the underlying PCB is approximately 16 ppm, for example. These differences in CTE will cause stress in the various interconnects upon temperature cycling, where the magnitude of the stress between any two components will increase with increasing differences in CTE between the components.

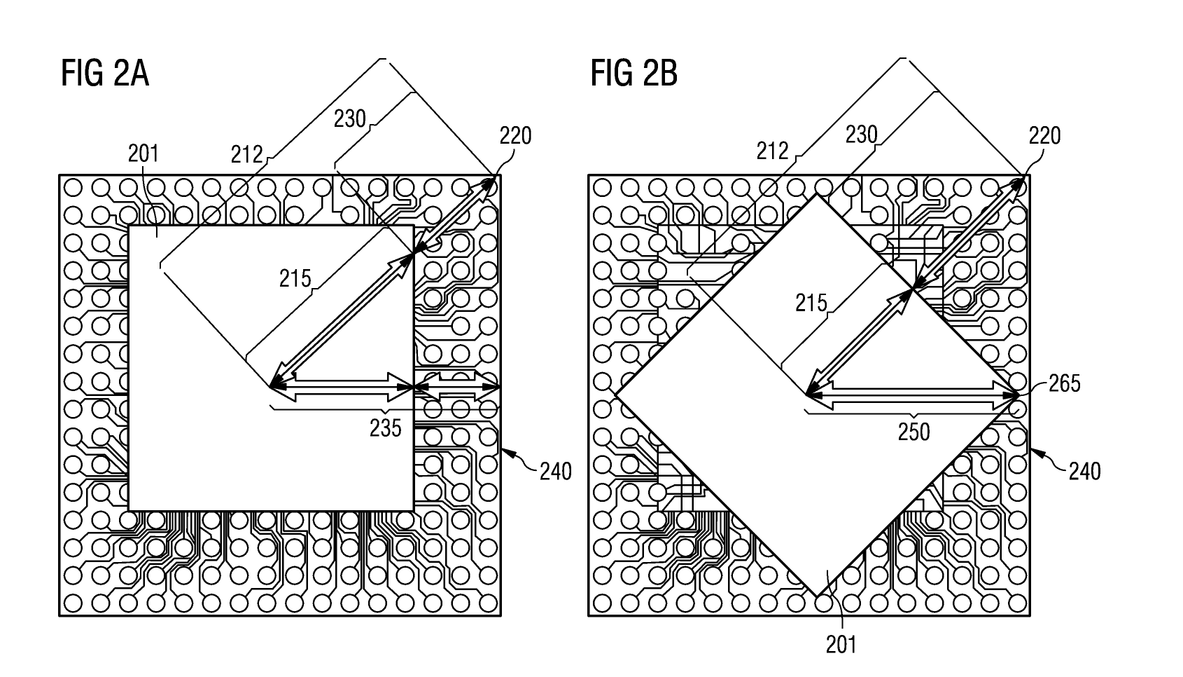

Another factor relating to the stresses upon the various interconnects in a package is the distance to neutral point (DNP), which is measured from the center of the semiconductor device to the location of a solder ball. The DNP is mainly important to any position where there is a solder ball in the package—the higher the DNP, the higher the stress in the solder ball. For instance, for the purposes of this aspect of the disclosure and with reference to FIG. 2A, there is a total DNP associated with the distance to the solder balls at the corner of the package 212 and a second DNP associated with the distance from the neutral position to the solder balls at the edge of the package 235. The larger DNP to solder balls at corner of package 212 versus that measured to the edge of the package 235 will contribute to increased stress on the interconnects located at the corner positions 220 of package versus those at the edge of package 240. Moreover, as shown in FIG. 2A, the total to the corner of package DNP 212 can thought of as having two components, the fraction of the total DNP associated with the semiconductor device 215 and the fraction of the total DNP associated with the polymeric mold compound 230.

FIG. 2B illustrates the effect of rotating semiconductor device 201 inside of the eWLB in one aspect of the disclosure. In this aspect, the effect on total DNP 212 in the direction of the package corner 212 is illustrated. In this illustration, the fraction of DNP associated with semiconductor device 215 has been reduced, while the fraction of DNP associated with epoxy molding compound 230 in package corner position 220 has increased.

As illustrated in FIG. 2B, as a result of the rotation, there is an relative increase in the amount of mold compound located in the corner of the package versus the non-rotated configuration. Correspondingly, there is a net decrease of the amount of semiconductor device 201 material located in the corner of the package. As discussed previously, a typical CTE for highly-filled mold compound can be 7 ppm, while that of a silicon semiconductor device can be 3 ppm. Moreover, the net CTE of an area of the package can be directly related to the amount of a material of a given CTE in that area of the package. Therefore, an increase in the amount of mold compound located in the corner of the package means that the net CTE associated with the corner region of the package is higher, because the higher CTE mold compound makes up a larger fraction of this area. This lead to an overall decrease in the total CTE mismatch in the corner region of the package, because the CTE of the mold compound is more closely matched to that of the underlying PCB (e.g., 16 ppm).

In another aspect of the disclosure, this may lead to a decrease in failures with thermal cycling because there is less of a CTE mismatch in the corner region, where there is a higher interconnect density.

Moreover, in another aspect of the disclosure, following rotation of semiconductor device 201 the corners 265 of semiconductor device 201 have been translated to an area nearer to the outer edge of package 240. This, of course, increases the portion of total DNP associated with semiconductor device material 250, and hence the amount of semiconductor material, that falls within edge 240 of package 200. This leads to some increase in stress in this area due to a net increase in the CTE mismatch in the edge 240 region of package 200. However, the increase is small compared to the decrease in stress associated with the corner position. This leads to an overall increase in reliability for the package.

Note that, although a rotation of approximately 45 degrees is used in tOis example, in another aspect of the disclosure, the rotated package design is not limited to this angle. Indeed, the angle may vary widely depending on application, and thus the current illustration should not be seen as limiting. In an aspect of the disclosure, the angle of rotation may vary, for example, between 45±5°. This orientation may be beneficial, for instance, in the case when the semiconductor device area to package size ratio is relatively high, in other words when there is a relatively small semiconductor device in a relatively large package. In a further aspect of the disclosure, an angle of 45±10° may be appropriate.

In contrast, an angle of 22.5°±5° may be more beneficial when the semiconductor device to package area ratio is relatively low, in other words when the semiconductor device is relatively large compared to the package. In a further aspect of the disclosure, an angle of 22.5°±10° may be appropriate

Moreover, in another aspect of the disclosure, although an approximately square semiconductor device is shown in the Figures, the semiconductor device may take any shape used in the art, and thus the shape of the semiconductor device is in no way limiting with respect to this disclosure.

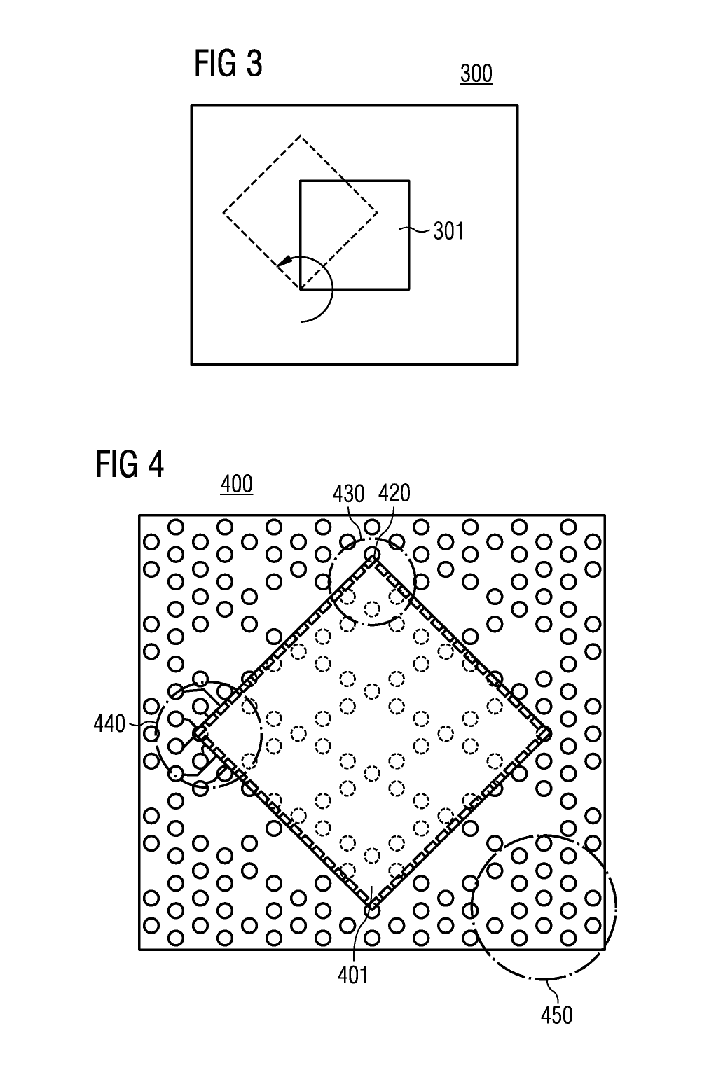

Further, the axis of rotation of the semiconductor device is not limited to the center of the semiconductor device. Rotation about one corner of semiconductor device 301 is another aspect of this disclosure, as shown in FIG. 3. Therefore, as illustrated in FIG. 3, rotation of semiconductor device 301 may lead to semiconductor device 301 that is not only rotated, but that is translated with respect to its original position in package 300. This may be useful in a situation where, for instance, design considerations necessitate a greater redistribution trace density on one edge of the package than the other.

In another aspect of the disclosure, rotation of semiconductor device 401 within package 400 leads to a decrease in the distance from the chip corner to the package edge, as is illustrated in FIG. 4. This brings high-density contact regions 420 at the edge of semiconductor device 401 much closer to, and in some cases overlapping with, bond pads 430 at the edge of the package 400. In a another advantage of the current rotated package design, this results in, for example, shorter interconnects 440 in the region of the higher-density edge contact region. Shorter interconnects 440 may result in better electrical performance due to decreased conductor length. Moreover, the reduced interconnect length also may contribute to improved device reliability. As the length of the interconnects 440 increase, there is, of course, increased exposure to opens in the interconnect 440.

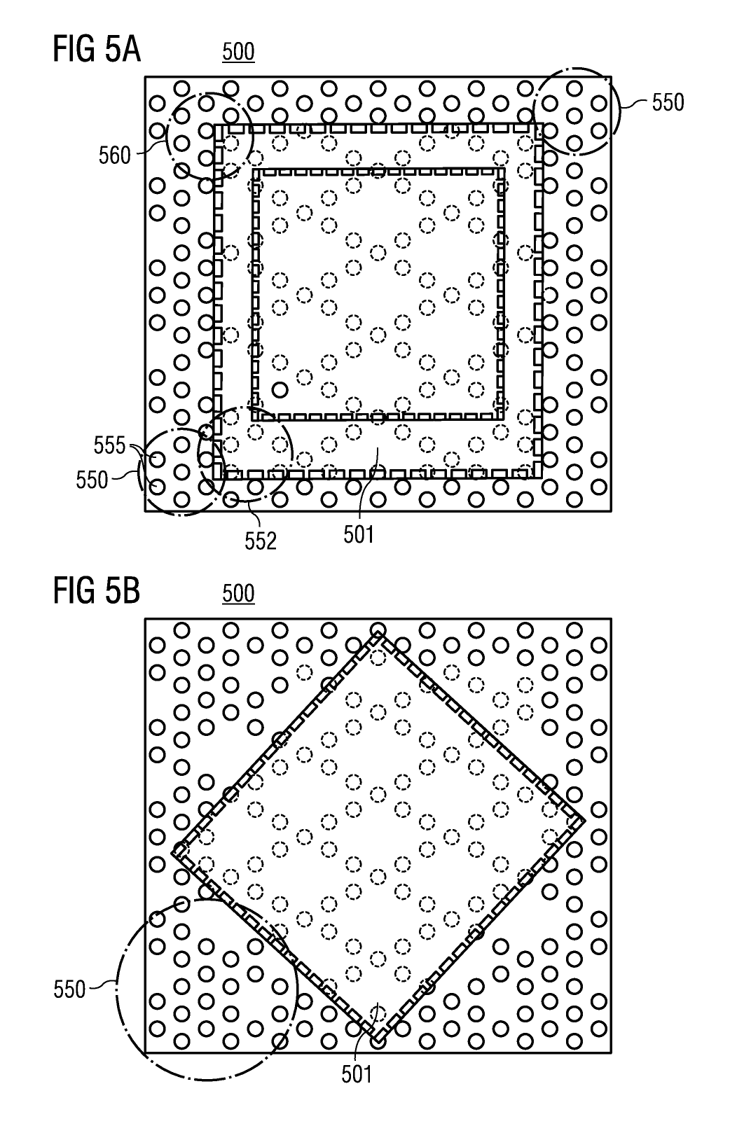

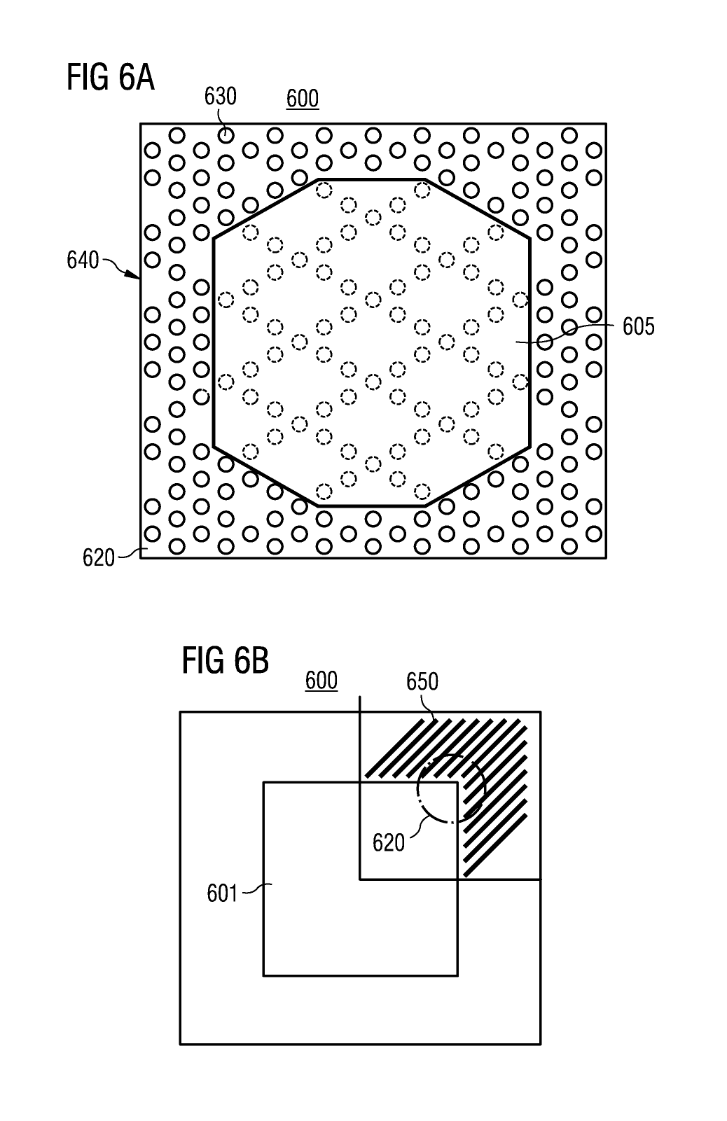

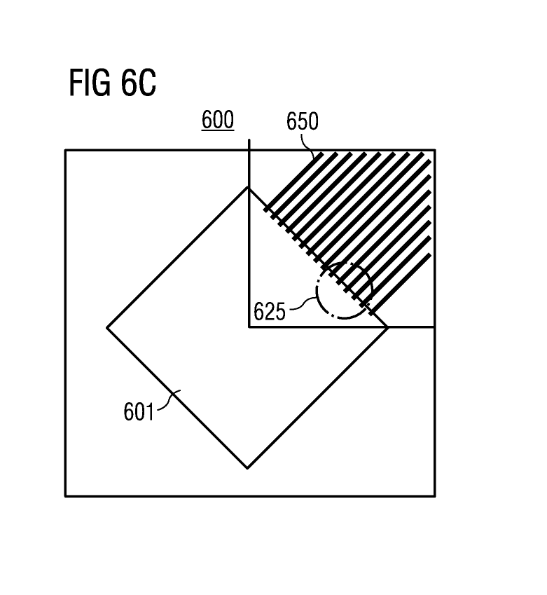

Moreover, as further illustrated in FIG. 5 in another aspect of the disclosure, semiconductor device rotation creates more space within the package corners 550. As illustrated in FIG. 5A, in a standard semiconductor device/package orientation there are tight space restrictions in the corners of package 550 due to the high density of inputs resulting from the combination of the high pad density 552 at the semiconductor device corner with the high redistribution trace density 555 (hence, large number of ball pads) at package corners. This is because there are many solder balls in the package corner because the package design typically has no depopulations (balls of the matrix which are not in the design). On the semiconductor device, in contrast, there is solder ball depopulations 565 (e.g. no ball allowed over certain areas of the chip). Further, typical symmetrical orientation of the semiconductor device within the mold compound of the package means that there is less space available for routing the redistribution traces in the package corners, as the corner 560 of semiconductor device 501 projects into the corner 550 of package. Rotation of semiconductor device 501 within package 500 frees up additional space within the mold compound at the corners 550 of package, as shown at FIG. 5B. This additional space can be used for routing of redistribution traces, if desired. This may allow for greater flexibility in design. This avoids, for example, the need to apply two or more metal layers through a so-called multi-layer redistribution. Also, this may allow for relaxed design and manufacturing requirements in that the manufacturing tolerances may be lessened due to the decreased need to avoid overlap of tightly-spaced conductors, for example. Less tight routing of the redistribution traces may also result in improved reliability as well. FIGS. 6A-6C illustrate this aspect of the disclosure below.

FIG. 6A illustrates a typical pattern of solder pads 630 that would be required to align with the plated-through holes (PTH) of a printed circuit board (PCB)(not shown). Center region 605 of package 600 exhibits a relative depopulation of solder pads compared to edges 640 and corners 620. As discussed above, corner 620 of package 600 is highly populated with redistribution lines, and hence solder pads 630. This is a consquence of moving out the contacts to the underlying PCB from underneath the semiconductor device and “fanning out” the connections.

FIG. 6B illustrates a current, non-rotated semiconductor device 601 placement in relation to the package. An exemplary redistribution trace arrangement is illustrated in corner 650 of package 600. As shown, the corner region of package 600 is bonded through the two sides of semiconductor device corner 620. As discussed above, semiconductor device corner 620 has a high line routing and pad placement density. This makes routing of the various redistribution lines from the package corner into the corner region of the semiconductor device difficult, imposing very strict design rule requirements.

The advantage of a rotated semiconductor device placement is illustrated in FIG. 6C. Here it is shown that routing can be more easily achieved after rotation. The redistribution traces 650 now electrically attach to semiconductor device 601 on edge 625, thus simplifying the routing scheme.

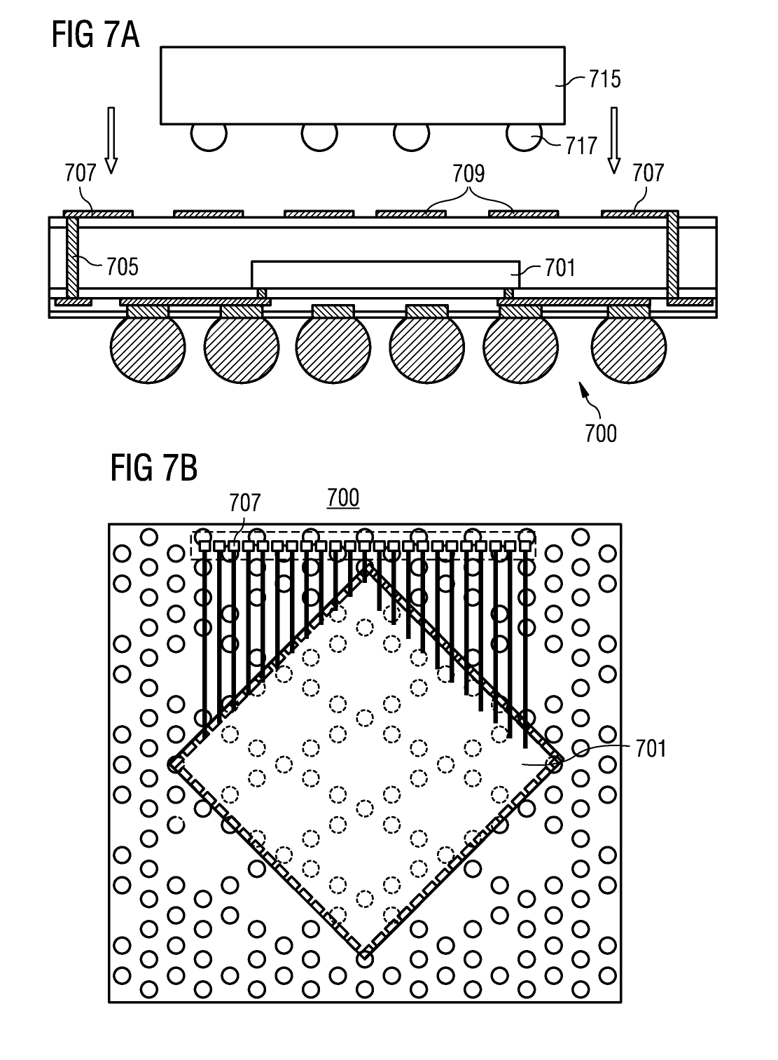

Yet another advantage of the current rotated semiconductor device eWLB package is illustrated in FIGS. 7A and 7B. In this aspect of the disclosure, a rotated semiconductor device eWLB package is incorporated into an advance package-on-package (PoP) option, allowing for improved stacked package connection. FIG. 7A illustrates a typical PoP package design. Lower semiconductor device 701 is electrically connected to the upper part of the eWLB package through metal interconnects 705, called vias 705, and upper-level redistribution traces 707. Vias 705 can be formed in a number of methods known in the art including, but not limited to, as a pre-filled via or as laser-drilled vias. The type of via 705 formed is not limiting with respect to the use of the rotated semiconductor device eWLB package that is the subject of this disclosure. A second package 715 including at least one semiconductor device (not shown) is attached to lower package 700 by solder balls 717 on the upper semiconductor device to pads 709 terminating from traces originating from the vias 705 on the lower level package 700.

FIG. 7B shows a plan view of via 707 structure in bottom package 700. Lower semiconductor device 701 is in rotated position, in accordance with an aspect of the disclosure. Vias 707 are aligned, in this instance, along one edge of lower package 700. Because semiconductor device 701 is rotated within package 700, there are two semiconductor device 701 edges exposed to vias 707. This means that connection of vias 707 to bottom semiconductor device 701 is simplified, as less routing is necessary to access the two sides of the semiconductor device. Disposed over lower semiconductor device 701 is an upper semiconductor device (not shown), which is electrically connected to lower semiconductor device 701 in a manner consistent with that illustrated in FIG. 7A through vias 707.

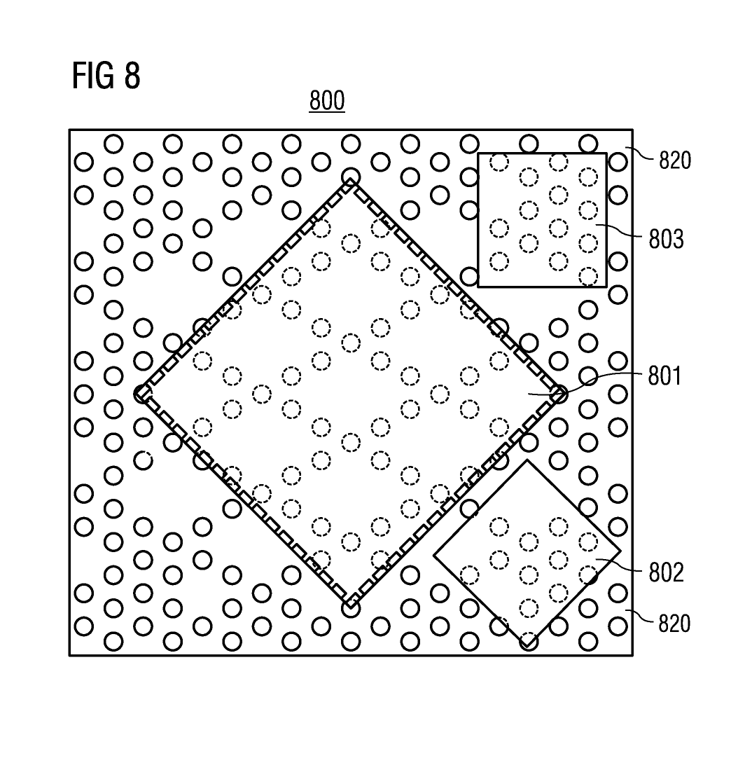

FIG. 8 illustrates yet another aspect of the disclosure. Here, rotation of semiconductor device 801 allows the addition of other, smaller semiconductor device 802, 803 into package 800. Examples of combinations of devices that may be incorporated into package 800 include RF receiver and digital device, CMOS power amplifier and integrated passive devices, and memory controller. The application according to this aspect of the disclosure is not limited to these combinations, however. The multi-chip packages disclosed herein are broadly applicable to many different combination of chips which may be useful in a given application. As shown in FIG. 8, the rotation of semiconductor device 801 within package 800 frees up additional room at the corners 820 of package 800. Smaller semiconductor device 802, 803, like large semiconductor device 801, may be oriented in virtually any angle with respect to the edges of the package. For example, in FIG. 8, one smaller semiconductor device 802 is rotated at approximately 45 degrees with respect to the package, while second smaller semiconductor device 803 is not rotated. Note that the number of semiconductor device which may be accommodated due to rotation is also not limited by the current rotated semiconductor device package design, and the number of devices which may be incorporated may vary widely depending on the application.

Semiconductor device arrangements in accordance with some aspects of the disclosure described herein (for example, the semiconductor device arrangement in accordance with the embodiment shown in FIGS. 1-6) may, for example, also be used with or configured as a wire bond package, in other words as a package where bond pads are contacted by means of a wire bonding process.

A person skilled in the art will recognize that combinations of the above exemplary embodiments may be formed. For example, a package-on-package configuration as disclosed in FIGS. 5A-5B may be combined with configurations including additional semiconductor device, as disclosed in FIG. 6. Of course, any or all of the semiconductor device included in these configurations may be rotated to the degree discussed herein. Alternatively, only some of the semiconductor device may be rotated. For instance, the use of a rotated PoP configuration according to FIGS. 7A-B may result in reduced DNP to various ball pads, for instance, or decreased stress on various interconnect elements due to improved CTE matching, for instance. Similarly, the ability to include additional semiconductor device according to FIG. 8 may result in reduced DNP, improved CTE matching, or improved routing of interconnects according to FIGS. 2, 4 and 6, for instance. Moreover, the rotation of a semiconductor device about a corner of the semiconductor device according to FIG. 3 may also result in any of the benefits disclosed in FIG. 2, or 4-7, for example.

Semiconductor device arrangements in accordance with some aspects of the disclosure described herein may, for example, also be used in connection with a flip chip process.

While the invention has been particularly shown and described with reference to specific aspects of the disclosure, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A device package, comprising:
at least one semiconductor device rotated about an axis with respect to an edge of the package;
at least one bond pad on each semiconductor device; and
at least one conductive trace electrically connected to the semiconductor device through the at least one bond pad.

2. The device package of claim 1, wherein the at least one semiconductor device is rotated in a range of approximately 40 to 50 degrees around the central axis of the semiconductor device.

3. The device package of claim 1, wherein the at least one semiconductor device is rotated in a range of approximately 40 to 50 degrees around the central axis of the semiconductor device.

4. The device package of claim 1, wherein the at least one semiconductor device is rotated in a range of approximately 17.5 to 27.5 degrees around the central axis of the semiconductor device.

5. The device package of claim 1, wherein the at least one semiconductor device is rotated in a range of approximately 17.5 to 27.5 degrees around the central axis of the semiconductor device.

6. The device package of claim 1, wherein the at least one semiconductor device is rotated about an axis other than the central axis of the semiconductor device.

7. The device package of claim 2, further comprising a second semiconductor device that is not rotated with respect to the package.

8. The device package of claim 1, further comprising at least one further semiconductor device located over the at least one semiconductor device.

9. The device package of claim 8, wherein the semiconductor device are electrically connected.

10. The device package of claim 1, configured as an embedded wafer level ball grid array.

11. A method of manufacturing a device, the method comprising:
providing a package;
providing at least one semiconductor device;
forming at least one bond pad on one semiconductor device;
orienting the at least one semiconductor device within the package wherein at least one side of the semiconductor device is not parallel with at least one side of the package; and
forming at least one redistribution trace that electrically connects the semiconductor device with the at least one bond pad.

12. The method of claim 11, wherein the semiconductor device is rotated around a central axis of the semiconductor device.

13. The method of claim 12, wherein the semiconductor device is located substantially at the center of the package.

14. The method of claim 12, wherein the semiconductor device is rotated around an axis not at the center of the semiconductor device.

15. The method of claim 11, wherein at least one non-rotated semiconductor device is included within the package.

16. The method of claim 11, further comprising positioning at least one further semiconductor device over the least one semiconductor device.

17. The method of claim 15, further comprising forming an electrical contact between the at least one semiconductor device and the at least one further semiconductor device.

18. A device, comprising:
a package;
at least one semiconductor device oriented with at least one side that is not parallel with a side of the package; and
at least one redistribution trace electrically connected to the semiconductor device.

19. The device of claim 18, wherein the semiconductor device is rotated around a central axis of the semiconductor device.

20. The device of claim 19, wherein the semiconductor device is located substantially at the center of the package.

21. The device of claim 18, wherein the semiconductor device is rotated around an axis not at the center of the semiconductor device.

22. The device of claim 18, including at least one non-rotated semiconductor device within the package.

23. The method of claim 18, further comprising positioning at least one further semiconductor device over the least one semiconductor device.

24. The method of claim 23, further comprising forming an electrical contact between the at least one semiconductor device and the at least one further semiconductor device.
